(19) United States
(12) Patent Application Publication
(10) Pub. No.: US 2004/0135651 A1
(43) Pub. Date: Jul. 15, 2004

(54) Filter arragement

(76) Inventor: Dirk Heumann, Nidderau (DE)

Correspondence Address: JOHN S. PRATT, ESQ, KILPATRICK STOCKTON, LLP, 1100 PEACHTREE STREET, SUITE 2800, ATLANTA, GA, 30309, US

(21) Appl. No.: 10/469,879

(22) PCT Filed: Feb. 28, 2002
(86) PCT No.: PCT/EP02/02190

(30) Foreign Application Priority Data
Mar. 8, 2001 (DE) 101 11 151.7

(51) Int. Cl. H03H 7/01

(52) U.S. Cl. 333/175

(57) ABSTRACT

A filter arrangement for replacing a standard filter for notch diplexers in telephone networks comprising a shunt arm and two longitudinal arms in a T arrangement, wherein the first longitudinal arm has a first inductance (L1), the second longitudinal arm has a second inductance (L3), and the shunt arm has a third inductance (L2), in addition to comprising a capacitor (C2) arranged in a series. The third inductance (L2) is increased in relation to the standard filter and the capacitor (C2) is correspondingly reduced, whereby a neutral point is maintained inside a given area.

The invention relates to a filter arrangement to replace a standard filter for notch diplexers in telephone networks, in particular distributed notch diplexers, with a shunt arm and two longitudinal arms in a T arrangement in which the first longitudinal arm has a first inductor, the second longitudinal arm has a second inductor, and the shunt arm has a third inductor and a capacitor in series.

ADSL is a broadband telecommunications technology which connects the end subscriber to the exchange. In this case ADSL stands for Asymmetric Digital Subscriber Line. The transmission rates are asymmetric with a high transmission rate (>1.5 Mbit/s) from the exchange to the end subscriber and a low transmission rate (<800 kbit/s) from the end subscriber to the local exchange. However, digital and/or analog telephone conversations (ISDN=Integrated Services Digital Network, POTS=Plain Old Telephone System) should be able to be conducted simultaneously over the same line with a data transmission (ADSL). So that ISDN, POTS, and ADSL cannot affect one another a notch diplexer (high-pass filter and low-pass filter) is connected to the end of the line, said notch diplexer conducting the ADSL data to the ADSL modem via the high-pass filter and the conversations to the ISDN/POTS end device via the low-pass filter. These notch diplexers can on the one hand be designed as a central ADSL splitter (notch diplexer) at the transition to the internal telephone network and on the other hand as distributed splitters at each end device. For distributed splitters so-called microfilters are used.

Special demands are made on the microfilter with respect to insertion loss, insertion loss distortion, stopband attenuation, and reflection loss, as is presented, for example, in the draft standard ANSI-T1.413-110R4. Therein it is problematic that microfilters in practical operation can be connected in parallel since they can be connected to each end device of the internal telephone network. If the microfilter is connected as a standard filter, this then leads to an insertion loss and an insertion loss distortion which are much too large and a reflection loss which is much too small.

The transmission function of a standard filter is given by

|H(p)|²=1/(1+Pₙ(P)²)

with p=2πif and a polynomial Pₙ(p) of nth order. These polynomials are Tschebyscheff filters, Jacobi functions for Cauer filters, etc. (cf., for example, Ashok Ambardar, “Analog and Digital Signal Processing,” PWS Publishing Company, Boston, 1995).

The polynomials are chosen so that they optimize filter characteristics. They minimize, for example, the group delay distortion (Bessel filter) or the stopband attenuation (Cauer filter).

This type of configuration of the filters leads to fixed classes of filters, the so-called standard filters. They are distinguished, for example, by the fact that the inductance in the shunt arm is significantly smaller than the inductance in the longitudinal arm.

In FIG. 1 a microfilter MF, realized as a third-order standard filter with a passband of 8 kHz, is represented. The microfilter MF comprises an inductor L1 with an inductance of 9.5 mH in a longitudinal arm oriented toward the source, a series circuit of a capacitor C2 with a capacitance of 33 nF and an inductor L2 with an inductance of 0.92 mH in the shunt arm, and an inductor L3 with an inductance of 9.5 mH in the longitudinal arm turned toward the load. The filter is terminated by an ohmic resistance RO of 600 Ω. On the supply side the standard filter is connected to a source Q via a transmission line. The equivalent circuit diagram of the transmission line includes a resistor R1 in the longitudinal arm as well as a series circuit of a capacitor C1 with a capacitance of ca. 100 nF and an ohmic resistor R2 with a resistance of ca. 348 Ω in the shunt arm.

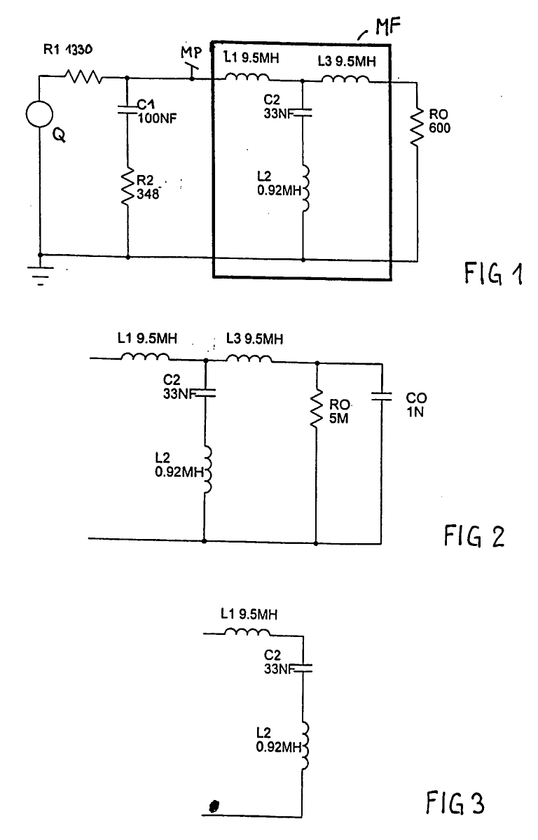

At one node point MP, turned away from a reference potential, between the transmission line and standard filter, four microfilters must be introduced in the manner shown in FIG. 2 for the insertion loss measurement for one telephone off the hook and four telephones on the hook. This means that a standard filter with the inductors L1, L2, and L3 as well as a capacitor C2 is terminated with a resistor RO with a resistance of 5 MΩ as well as a capacitor CO with a capacitance of 1 nF.

In the speech region this arrangement is reduced to the inductors L1 and L2 as well as the capacitor C2 (compare FIG. 3). This means that along with the transmission function neutral point at 28.8 kHz (L2, C2) an additional one occurs at 8.5 kHz (L1+L2, C2), which however leads to a strong insertion loss in the speech region (up to 4 kHz). The sum of the inductances L1 and L2 leads to the neutral point arising in the vicinity of the speech region. With this, the inductance L1 cannot be reduced due to the required stopband attenuation at 25 kHz. The equivalent circuit diagram with four microfilters with telephone off the hook (FIG. 3) would give the result that the arm shown in FIG. 3 is connected four times at the point MP in FIG. 1.

It is the objective of the invention to specify a filter arrangement which is improved in regard to insertion loss, insertion loss distortion, and reflection loss with respect to a standard filter, where the neutral point should be maintained in the stopband region.

This objective is realized by a filter arrangement according to claim 1. Developments and extensions of the concept of the invention are the object of subordinate claims.

In detail the objective is realized with a filter arrangement of the type stated initially by the fact that relative to the standard filter the third inductance is increased and the capacitance correspondingly reduced so that the neutral point remains within a given region. In particular, the third inductance and capacitance are changed so that the neutral point remains in the stopband region.

The first and/or second inductance can be increased with respect to the standard filter.

Furthermore, it can be provided that a single coil with pick-off is provided as second and third inductor, where the coil can be wound on a core. In this way the necessary expenditure (in particular expenditure in winding) and the size can be reduced.

In a development of the invention as low-pass filter of a splitter for ADSL applications, the first and second inductances are, for example, each equal to 10 mH, the third inductance is equal to 9 mH, and the capacitance is equal to 4 nF, where one starts from a basic standard filter with a first and second inductance of 9.5 mH each, a third inductance of 0.92 mH, and a capacitance of 33 nF.

With the use of a single coil with pick-off as second and third inductor, for example, the first inductance is equal to 14.7 mH, the second inductance is equal to 5.3 mH, the third inductance is equal to 4.3 mH, and the capacitance is equal to 4 nF, where once again one starts from said standard filter.

The invention is explained in more detail in the following with the aid of the drawings in the figures. Shown are:

FIG. 1 a standard filter according to the state of the art for use as an ADSL splitter,

FIG. 2 a standard filter with an impedance which represents a telephone off the hook,

FIG. 3 a simplified representation of the arrangement according to FIG. 2 for the speech region,

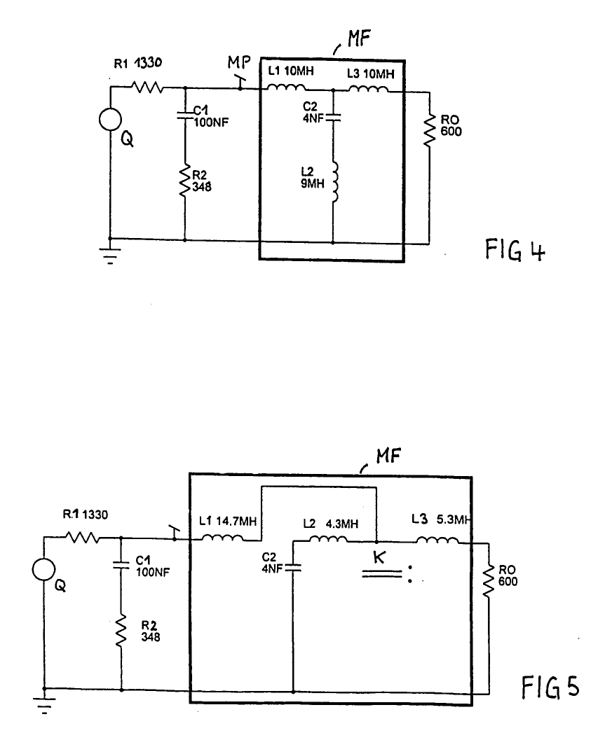

FIG. 4 a first embodiment example of a filter arrangement according to the invention,

FIG. 5 a second embodiment example of a filter arrangement according to the invention,

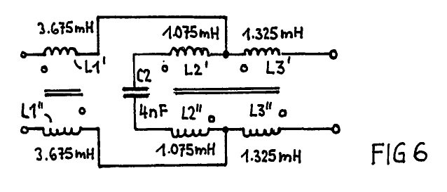

FIG. 6 a symmetric form of embodiment of the filter arrangement according to FIG. 5.

In the embodiment example shown in FIG. 4 the microfilter is modified with respect to the standard filter, according to the state of the art and shown in FIG. 1, with the aim of reducing the capacitance C2 from 33 nF to 4 nF and increasing the inductance L2 from 0.92 mH to 9 mH.

This filter arrangement has a transmission function neutral point at 26.5 kHz (L2, C2). Due to the design of the shunt arm the second neutral point only appears at 18.4 kHz (L1+L2, C2), that is, far outside of the speech region. Thereby the effect of the microfilters, connected in parallel, on insertion loss, insertion loss distortion, and reflection loss can be minimized while the neutral point relevant for stopband attenuation can be maintained.

In the embodiment example shown in FIG. 5, the inductors L2 and L3 are implemented as a single coil with a central pick-off, where the coil is wound on a core K. Thus, the pick-off of the coil is connected to the input via the inductor L1, which in this case has an inductance equal to 14.7 mH. A partial winding of the coil forms the inductor L2, which then has an inductance equal to 4.3 mH, and together with the capacitor C2, whose capacitance is equal to 4 nF, forms the shunt arm. The other part of the coil forms the inductor L3, which then has an inductance equal to 5.3 mH. In this way the number of inductors needed can be reduced, where advantageously the inductance values of the fewer inductors are smaller than those of the individual inductors. Furthermore, the expenditure in winding is less since the inductance values resulting from the reduction are smaller than the individual values of the unreduced version. In so doing, the filter arrangements according to FIGS. 4 and 5 are electrically equivalent.

Finally, in FIG. 6 the filter arrangement according to FIG. 5 is shown in symmetric implementation. In this embodiment example two symmetric individual coils with central pick-off which are wound on the core K are provided. Through the central pick-off two pairs of partial inductors L2′, L3′ or L2″, L3″ result which correspond to the inductors L2 and L3 from FIG. 5. The partial inductors are in this case electrically connected to one another via the capacitor C2. The partial inductors lead ultimately to the output of the filter arrangement. The central pick-offs of the two coils wound on the core K are each connected, via a partial inductor L1′, [sic] L″, to the input of the filter arrangement. The partial inductors L1′, L1″ are in turn magnetically coupled to one another via a core M and correspond to the inductance L1 from FIG. 5.

1. Filter arrangement to replace a standard filter for notch diplexers in telephone networks with a shunt arm and two longitudinal arms in a T arrangement in which
the first longitudinal arm has a first inductor (L1),
the second longitudinal arm has a second inductor (L3),
the shunt arm has a third inductor (L2) as well as a capacitor (C2) in series, characterized by the fact
that relative to the standard filter the third inductance (L2) is increased and the capacitance (C2) correspondingly reduced so that the neutral point remains within a given region.

2. Filter arrangement according to claim 1, characterized by the fact that the first and/or second inductance are increased with respect to the standard filter.

3. Filter arrangement according to one of the claims 1 or 2, characterized by the fact that a single coil with pick-off is provided as second or third inductor (L3, L2).

4. Filter arrangement according to claim 3, characterized by the fact that the coil is wound on a core (K).
